(19) United States
(12) Patent Application Publication
(10) Pub. No.: US 2019/0280136 A1
(43) Pub. Date: Sep. 12, 2019

(54) SOLAR CELL MODULE

(71) Applicant: PANASONIC INTELLECTUAL PROPERTY MANAGEMENT CO., LTD., Osaka (JP)

(72) Inventors: Naoki KURIZOE, Osaka (JP); Takeshi UEDA, Hyogo (JP); Yoshimitsu IKOMA, Nara (JP); Motohiko SUGIYAMA, Osaka (JP)

(21) Appl. No.: 16/349,133

(22) PCT Filed: Feb. 1, 2018
(86) PCT No.: PCT/JP2018/003425

§ 371 Date: May 10, 2019

(30) Foreign Application Priority Data
Feb. 16, 2017 (JP) 2017-026998
Oct. 31, 2017 (JP) 2017-210977

(51) Int. Cl. H01L 31/042; H02S 40/36; H01L 31/02

(52) U.S. Cl. CPC H01L 31/042; H01L 31/02008; H02S 40/36

(57) ABSTRACT

A solar cell module includes a front surface protective substrate including transparent resin, a rear surface protective substrate, and a photoelectric converter including at least one solar cell connected via a tab lead and arranged between the front surface protective substrate and the rear surface protective substrate. The solar cell module further includes at least one reinforcing layer, at least one seal layer, and a gel polymer layer, which are arranged between the photoelectric converter and the front surface protective substrate.

### TECHNICAL FIELD

The present invention relates to solar cell modules, and more particularly, to a solar cell module including a front surface protective substrate which includes transparent resin.

### BACKGROUND ART

A solar cell module typically includes a first substrate (a front surface protective substrate), a first resin layer (a seal layer), a photoelectric converter, a second resin layer (a seal layer), and a second substrate (a rear surface protective substrate), which are sequentially stacked. The photoelectric converter is covered with the first substrate and the first resin layer on one side, and the second resin layer and the second substrate on the other side, so as to be protected on both of the front and rear surfaces. Such a photoelectric converter includes a plurality of solar cells arranged into a matrix form and electrically connected to each other via tab leads (refer to Patent Document 1, for example). The electrical connection of the adjacent solar cells via the tab leads increases the output voltage of the photoelectric converter, for example.

A glass substrate, which has been used as a protective substrate in a solar cell module, is being replaced with a resin substrate in view of a reduction in weight. Such a recent solar cell module includes protective substrates arranged on both of the front and rear sides which differ in material depending on the function to be required so as to choose a material appropriate for each protective substrate.

### CITATION LIST

### Patent Literature

Patent Document 1: Japanese Patent Application Publication No. 2013-145807

### SUMMARY OF INVENTION

A coefficient of linear expansion is typically greater for resin than for glass, and resin is thus greatly influenced by thermal expansion or contraction caused by a change in temperature. The front surface protective substrate including resin, if thermally expanding or contracting, causes a stress applied to the resin layer bonded to the front surface protective substrate. A thermal stress applied to the front surface protective substrate or the resin layer tends to increase in proportion to a degree of a change in temperature caused in the solar cell module.

A large thermal stress applied to the resin layer in association with the change in temperature in the solar cell module may cause damage to the solar cells adjacent to the resin layer, or may cause a cutoff of the tab leads electrically connecting the solar cells.

In view of the foregoing conventional problems, the present invention provides a solar cell module resistant to damage to solar cells or cutoff of tab leads when a change in temperature is caused.

In order to solve the problems described above, a solar cell module according to a first aspect of the present invention includes a front surface protective substrate including transparent resin, a rear surface protective substrate, and a photoelectric converter including at least one solar cell connected via a tab lead and arranged between the front surface protective substrate and the rear surface protective substrate. The solar cell module further includes at least one reinforcing layer, at least one seal layer, and a gel polymer layer, which are arranged between the photoelectric converter and the front surface protective substrate.

A residential structure material according to a second aspect of the present invention includes the solar cell module according to the first aspect.

An outdoor facility according to a third aspect of the present invention includes the solar cell module according to the first aspect.

A transport according to a fourth aspect of the present invention includes the solar cell module according to the first aspect.

### BRIEF DESCRIPTION OF DRAWINGS

FIG. 1 is a top view showing a solar cell module according to an embodiment of the present invention.

FIG. 2 is a partial cross-sectional view of the solar cell module shown in FIG. 1.

FIG. 3 is a partial cross-sectional view of the solar cell module having a configuration different from FIG. 2.

FIG. 4 is a partial cross-sectional view of the solar cell module having a configuration different from FIG. 2.

FIG. 5 is a partial cross-sectional view of the solar cell module having a configuration different from FIG. 2.

FIG. 6 is a partial cross-sectional view of the solar cell module having a configuration different from FIG. 2.

FIG. 7 is a cross-sectional view showing a particular state of a reinforcing layer and a gel polymer layer shown in FIG. 6.

FIG. 8 is a partial cross-sectional view of a configuration similar to FIG. 2, further including a reinforced layer arranged toward a rear surface protective substrate.

### DESCRIPTION OF EMBODIMENTS

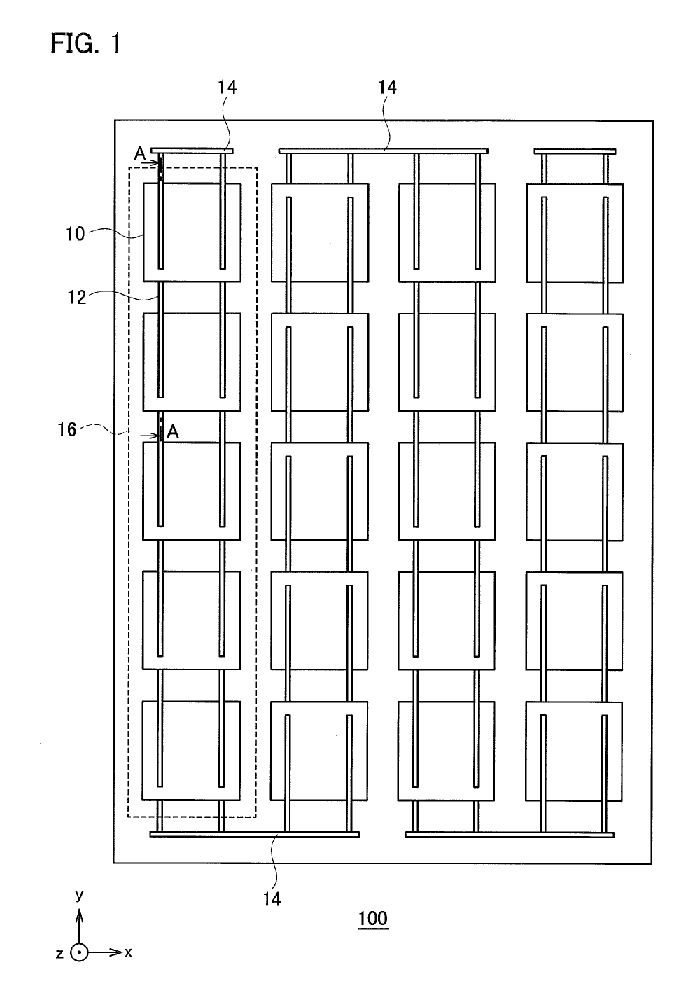

A solar cell module according to the present embodiment will be described below with reference to the drawings. FIG. 1 is a top view showing the solar cell module 100 according to the present embodiment. As shown in FIG. 1, a three-dimensional coordinate system is defined by x, y, and z axes. The x axis and the y axis are orthogonal to each other in the plane of the solar cell module 100. The z axis is orthogonal to each of the x axis and the y axis, and extends in the thickness direction of the solar cell module 100. The positive direction of the respective x, y, and z axes conforms to the direction indicated by the corresponding arrow shown in FIG. 1, and the negative direction is opposite to the direction indicated by the corresponding arrow. One of the two main surfaces of the solar cell module 100 parallel to the x-y plane and located toward the positive direction of the z axis is defined as a “light-receiving surface”, and the other main surface located toward the negative direction of the z axis is defined as a “rear surface”. As used herein, the term “light-receiving surface” also refers to a surface on which light is mainly incident, and the term “rear surface” also refers to a surface on the opposite side of the light-receiving surface for illustration purposes. The side toward the positive direction of the z axis is referred to also as a “light-receiving surface side”, and the side toward the negative direction of the z axis is referred to also as a “rear surface side”.

The solar cell module 100 includes a plurality of solar cells 10, a plurality of tab leads 12, and a plurality of connecting leads 14. Each of the solar cells 10 absorbs incident light to generate photovoltaic power. The respective solar cells 10 are made of semiconductor material such as crystalline silicon, gallium arsenide (GaAs), or indium phosphide (InP). The solar cells 10 may have any structure, and is herein presumed to have a structure including crystalline silicon and amorphous silicon stacked on each other, for example. Although not shown in FIG. 1, the light-receiving surface and the rear surface of each solar cell 10 are provided with a plurality of finger electrodes extending in parallel in the x-axis direction, and a plurality of, for example, two busbar electrodes extending in the y-axis direction perpendicular to the finger electrodes. The busbar electrodes connect the respective finger electrodes.

The plural solar cells 10 are arranged into a matrix form on the x-y plane. In this embodiment, four solar cells 10 are aligned in the x-axis direction, and five solar cells 10 are aligned in the y-axis direction. The number of the solar cells 10 aligned in each of the x-axis direction and the y-axis direction is not limited to the illustration above. The five solar cells 10 aligned in the y-axis direction are connected in series via the tab leads 12 so as to compose a single solar cell string 16. As described above, the four solar cells 10 are aligned in the x-axis direction, and the four solar cell strings 16 each elongated in the y-axis direction are thus arranged in parallel in the x-axis direction. The respective solar cell strings 16 are illustrated with a combination of the plural solar cells 10 and the plural tab leads 12.

The solar cell string 16 is obtained such that the busbar electrode of each of the aligned solar cells 10 on the light-receiving surface side is electrically connected to the busbar electrode of its adjacent solar cell 10 on the side opposite to the light-receiving surface side via the tab leads 12. The adjacent two solar cells 10 are thus electrically connected to each other with the tab leads 12. The tab leads 12 are each made of a long narrow metal foil such that copper foil is soldered or coated with silver, for example. The tab leads 12 and the busbar electrodes are connected together with resin. The resin may be either conductive or nonconductive. For nonconductive resin, the tab leads 12 and the busbar electrodes are directly connected to each other to achieve electrical connection. Alternatively, the tab leads and the busbar electrodes may be connected by soldering, instead of resin.

The connecting leads 14 extend in the x-axis direction and electrically connect the adjacent two solar cell strings 16 on both sides of the y axis in the positive direction and the negative direction. In the configuration described above, each of the solar cells 10 and the solar cell strings 16 may serve as a “photoelectric converter”, or a combination of the solar cell strings 16 and the connecting leads 14 may serve as a “photoelectric converter”. The solar cell module 100 may be provided with a frame (not shown) along edge portions thereof. The frame is used to protect the edge portions of the solar cell module 100, and is also used upon the installation of the solar cell module 100 on a roof, for example.

The solar cell module according to the present embodiment includes a front surface protective substrate including transparent resin, a rear surface protective substrate, and a photoelectric converter including at least one solar cell 10 connected via the tab leads and arranged between the front surface protective substrate and the rear surface protective substrate. The solar cell module further includes at least one reinforcing layer, at least one seal layer, and a gel polymer layer, which are arranged between the photoelectric converter and the front surface protective substrate.

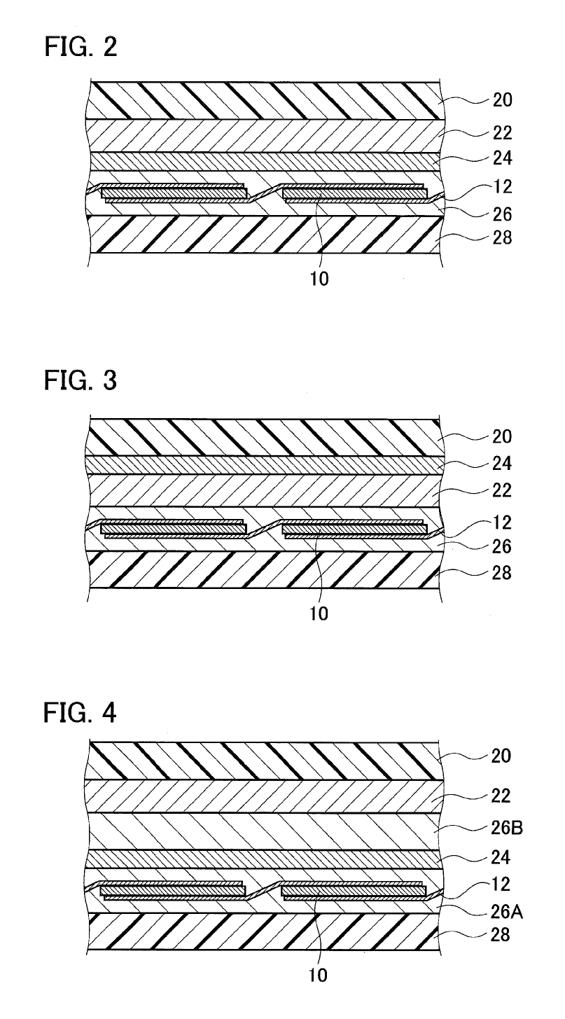

FIG. 2 is a cross-sectional view taken along line A-A in FIG. 1, showing part of the solar cell module 100. The solar cell module 100 includes the solar cells 10, the tab leads 12, the connecting leads 14, the solar cell strings 16, the front surface protective substrate 20, the gel polymer layer 22, the reinforcing layer 24, the seal layer 26, and the rear surface protective substrate 28. The upper side in FIG. 2 corresponds to the light-receiving surface (front surface) side, and the lower side corresponds to the rear surface side.

The front surface protective substrate 20 and the rear surface protective substrate 28 illustrated in FIG. 2 differ from each other in the constituent material. The front surface protective substrate 20 and the rear surface protective substrate 28 thus have different coefficients of thermal expansion. For example, the front surface protective substrate 20 includes polycarbonate, and the rear surface protective substrate 28 includes glass, as described below. The front surface protective substrate 20 has a greater coefficient of thermal expansion than the rear surface protective substrate 28. The respective surface protective substrates thus have different expansion/contraction behaviors derived from a change in circumferential temperature, as described above. In order to reduce the behavior difference, the solar cell module 100 according to the present embodiment includes the gel polymer layer 22 and the reinforcing layer 24 arranged between the front surface protective substrate 20 and the photoelectric converter. The solar cell module 100 according to the present embodiment can allow the gel polymer layer 22 arranged immediately under the front surface protective substrate 20 and having a small tensile modulus of elasticity to follow a deformation of the front surface protective substrate 20 caused by thermal expansion or contraction. Namely, the gel polymer layer 22 reduces the deformation of the front surface protective substrate 20. The reinforcing layer 24 having high mechanical strength is further arranged immediately under the gel polymer layer 22. The reinforcing layer 24 can further reduce the deformation of the front surface protective substrate 20 not absorbed sufficiently only by the gel polymer layer 22. The deformation of the front surface protective substrate 20 thus has little influence on the seal layer 26 or the photoelectric converter, preventing damage to the solar cells or a cutoff of the tab leads accordingly.

The respective layers will be sequentially described in detail below.

[Front Surface Protective Substrate]

The front surface protective substrate 20 is arranged on the side on which sunlight is incident in the solar cell module 100, and includes transparent resin. The transparent resin included in the front surface protective substrate 20 may be at least one material selected from the group consisting of polyethylene (PE), polypropylene (PP), cyclic polyolefin, polycarbonate (PC), polymethyl methacrylate (PMMA), polytetrafluoroethylene (PTFE), polystyrene (PS), polyethylene terephthalate (PET), and polyethylene naphthalate (PEN). The front surface protective substrate 20 particularly preferably includes PC, which has higher resistance to shock and higher transmittance, and is thus appropriate to protect the surface of the solar cell module 100. The front surface protective substrate 20 may include a hard coat layer on its surface including acrylic urethane, for example. The front surface protective substrate 20 or another layer such as the hard coat layer may contain an UV absorber, a gloss adjusting agent, or an antireflection agent.

The front surface protective substrate 20 preferably has a thickness set in a range of 0.1 mm to 15 mm, a tensile modulus of elasticity set in a range of 1.0 GPa to 10.0 GPa, and a total luminous transmittance set to 80% or greater. These parameters are described in detail below.

The thickness of the front surface protective substrate 20 is preferably set in the range of 0.1 mm to 15 mm, and more preferably in the range of 0.5 mm to 10 mm. The front surface protective substrate 20 with the thickness set in the above range can protect the solar cell module 100 sufficiently and can allow light to be transmitted to the photoelectric converter (the solar cells 10) efficiently.

The tensile modulus of elasticity of the front surface protective substrate 20 is preferably set in the range of 1.0 GPa to 10.0 GPa, and more preferably in the range of 2.3 GPa to 2.5 GPa. The front surface protective substrate 20 with the tensile modulus of elasticity set in the above range can protect the surface of the solar cell module 100 sufficiently. The tensile modulus of elasticity can be measured in accordance with JIS K7161-1 (Plastics—Determination of tensile properties—Part 1: General principles) as follows:

Eₜ=(σ₂−σ₁)/(ε₂−ε₁) (1)

where Eₜ is the tensile modulus of elasticity (Pa), σ₁ is a stress (Pa) measured at a distortion of ε₁=0.0005, and σ₂ is a stress (Pa) measured at a distortion of ε₂=0.0025.

The total luminous transmittance of the front surface protective substrate 20 is preferably set to 80% or greater, and more preferably set in a range of 90% to 100%. The front surface protective substrate 20 with the total luminous transmittance set in the above range can allow light to be transmitted to the photoelectric converter (the solar cells 10) efficiently. The total luminous transmittance can be measured in accordance with JIS K7361-1 (Plastics—Determination of the total luminous transmittance of transparent materials—Part 1: Single beam instrument), for example.

The coefficient of thermal expansion of the front surface protective substrate 20 is determined as appropriate, and may be set in a range of 40×10⁻⁶ K⁻¹ to 110×10⁻⁶ K⁻¹. According to the present embodiment, the presence of the gel polymer layer 22 and the reinforcing layer 24 barely leads to a problem derived from a deformation of the front surface protective substrate 20 if the front surface protective substrate 20 has a greater coefficient of thermal expansion and is thus easy to deform in association with a change in temperature. The coefficient of thermal expansion can be measured in accordance with JIS K7197:2012.

[Gel Polymer Layer]

The gel polymer layer 22 includes a gel polymer having high flexibility, and is arranged between the front surface protective substrate 20 and the photoelectric converter. The gel polymer layer 22 having flexibility follows the expansion or contraction of the front surface protective substrate 20, so as to prevent a stress caused by the expansion or contraction from being transferred to the photoelectric converter. The gel polymer layer 22 thus can reduce the stress caused by the expansion or contraction of the front surface protective substrate 20.

Various types of gels may be used for the material included in the gel polymer layer 22. The gels may be, but not necessarily, classified into a gel containing a solvent and a gel not containing a solvent. An example of a gel containing a solvent may be a hydrogel in which water is a dispersion medium, or an organogel in which an organic solvent is a dispersion medium. The gel containing a solvent may also be any of a gel with a number-average molecular weight of 10,000 or greater, an oligomer gel with a number-average molecular weight in a range of 1,000 or greater to less than 10,000, and a gel with a number-average molecular weight of less than 1,000. The gel polymer preferably includes at least one gel selected from the group consisting of silicone gel, urethane gel, acrylic gel, and styrene gel.

The gel polymer layer 22 has a thickness set in a range of 5% to 99% of the thickness of the front surface protective substrate 20, a tensile modulus of elasticity set in a range of 0.1 kPa or greater to less than 0.5 MPa, and a total luminous transmittance set to 80% or greater. These parameters are described in detail below.

The thickness of the gel polymer layer 22 is preferably set in the range of 5% to 99%, and more preferably in the range of 10% to 50% of the thickness of the front surface protective substrate 20. The gel polymer layer 22 with the thickness set in the above range can sufficiently reduce the stress caused by the expansion or contraction of the front surface protective substrate 20.

The tensile modulus of elasticity of the gel polymer layer 22 is preferably set in the range of 0.1 kPa or greater to less than 0.5 MPa, and more preferably in the range of 1 kPa or greater to 1 MPa or less. The gel polymer layer 22 with the tensile modulus of elasticity set in the above range can sufficiently reduce the stress caused by the expansion or contraction of the front surface protective substrate 20. The tensile modulus of elasticity of less than 0.5 MPa can particularly greatly decrease the shifted amount of the solar cells derived from a change in temperature, as described below, as compared with a case of the tensile modulus of elasticity of 0.5 MPa or greater (refer to Table 1). The tensile modulus of elasticity of 0.5 MPa is thus a critical value which can significantly reduce the stress caused by the expansion or contraction of the front surface protective substrate 20. The tensile modulus of elasticity is even more preferably set to 0.3 MPa or less, and still even more preferably set to 0.2 MPa or less, so as to reduce the stress caused by the expansion or contraction of the front surface protective substrate 20 more effectively.

The total luminous transmittance of the gel polymer layer 22 is preferably set to 80% or greater, and more preferably set in a range of 90% to 100%. The gel polymer layer 22 with the total luminous transmittance set in the above range can allow light to be transmitted to the photoelectric converter (the solar cells 10) efficiently. The method of measuring the total luminous transmittance is the same as described above.

[Reinforcing Layer]

The reinforcing layer 24 includes a material having high mechanical strength, and is arranged between the front surface protective substrate 20 and the photoelectric converter, as in the case of the gel polymer layer 22. The reinforcing layer 24 having high mechanical strength does not follow the expansion or contraction of the front surface protective substrate 20, so as to prevent the stress from being transferred to the photoelectric converter. The transfer of the stress caused by the expansion or contraction of the front surface protective substrate 20 is thus blocked by the reinforcing layer 24.

The reinforcing layer 24 can reduce the stress caused by the expansion or contraction of the front surface protective substrate 20 effectively together with the gel polymer layer 22 due to the complementary effect. The reinforcing layer 24 having high mechanical strength thus can sufficiently reduce the stress caused by the expansion or contraction of the front surface protective substrate 20 if the stress cannot be reduced satisfactorily only by the gel polymer layer 22.

The arrangement of the reinforcing layer 24 can achieve other effects in addition to the effects described above. The additional effects are described in detail below.

<Prevention of Undulation>

The gel polymer layer 22 would be arranged adjacent to the seal layer 26 if the reinforcing layer 24 is not provided. The gel polymer layer 22 is more flexible than the seal layer 26 and thus tends to be deformed to cause roughness when the solar cell module 100 is laminated with heating to be molded. The roughness in the gel polymer layer 22 tends to be caused particularly when the solar cell module 100 is laminated and molded in a vacuum. The roughness causes a difference in refractive index between the gel polymer layer 22 and the seal layer 26, and further leads the interface to be stressed due to the deformation to result in a poor appearance such as undulation. The arrangement of the reinforcing layer 24 having high mechanical strength between the gel polymer layer 22 and the seal layer 26 can prevent or reduce the deformation at the interface between the gel polymer layer 22 and the seal layer 26, so as to avoid a poor appearance. The reinforcing layer 24 preferably includes a thick and hard material in view of higher mechanical strength so as to prevent the deformation effectively. The difference in refractive index between the gel polymer layer 22 and the seal layer 26 adjacent to the reinforcing layer 24 is preferably minimized so as to further avoid a poor appearance.

<Prevention of Deformation of Gel Polymer Layer due to Shock>

For the case without the reinforcing layer 24 provided, the gel polymer layer 22 would be deformed by a stress applied from above (from the front surface protective substrate 20 side) when undergoing a steel-ball drop test, for example, so as to absorb impact energy. However, a local deformation would be caused toward the lower layer under the gel polymer layer 22 (toward the rear surface protective substrate 28), producing a local load to cause cracks in the solar cells 10. The arrangement of the reinforcing layer 24 having high mechanical strength between the gel polymer layer 22 and the seal layer 26 can prevent or reduce the deformation of the gel polymer layer 22 if a stress is applied from above, so as to prevent cracks in the solar cells 10 accordingly. The reinforcing layer 24 preferably includes a thick and hard material so as to prevent the deformation of the gel polymer layer 22 effectively.

<Facilitation of Bonding Process>

The gel polymer layer 22 has adhesive and tack characteristics, which may lead to a trouble with handling upon the bonding process such as laminating processing. The reinforcing layer 24 is thus provided between the gel polymer layer 22 and the seal layer 26, in particular, the reinforcing layer 24 is attached to one surface of the gel polymer layer 22 before being bonded together, so as to reduce the problem with the adhesion to improve handling performance. The reinforcing layer 24 preferably includes a thick, hard, and low-adhesive material so as to improve the handling performance.

<Prevention of Separation of Gel Polymer due to Oscillation>

The gel polymer layer 22 sometimes causes separation or entrance of bubbles when repeatedly receiving a load such as oscillations, which may lead to a trouble with the adhesion. The arrangement of the reinforcing layer 24 between the gel polymer layer 22 and the seal layer 26 can avoid these problems. The reinforcing layer 24 preferably includes a thick and hard material so as to prevent separation. The use of such a reinforcing layer 24 can improve the adhesion between the reinforcing layer 24 and the seal layer 26, but does not change the adhesion at the interface between the front surface protective substrate 20 and the gel polymer layer 22, leading to a problem of separation at the interface. In order to avoid separation at the interface, the area of the gel polymer layer 22 is preferably set to be smaller than the area of each of the front surface protective substrate 20 and the reinforcing layer 24 so as to bond the edge of the front surface protective substrate 20 and the edge of the reinforcing layer 24 together. This configuration allows the gel polymer layer 22 to be enclosed by the front surface protective substrate 20 and the reinforcing layer 24.

Examples of materials included in the reinforcing layer 24 include polyethylene, polypropylene, polystyrene, polyvinyl chloride, polyethylene terephthalate, polyethylene naphthalate, polybutylene terephthalate, polycarbonate, polyacetal, acrylic resin, polyamide resin, ABS resin, ACS resin, AES resin, ASA resin, a copolymer of these resins, fluororesin such as PVF, silicone resin, cellulose, nitrile resin, phenol resin, polyurethane, ionomer, polybutadiene, polybutylene, polymethylpentene, polyvinyl alcohol, polyarylate, polyether ether ketone, polyether ketone, polyether sulfone, and polyimide. Particularly preferable examples include polyethylene terephthalate, polyethylene naphthalate, polybutylene terephthalate, polycarbonate, and acrylic resin.

The reinforcing layer 24 preferably has a thickness set in a range of 10 μm to 200 μm, a coefficient of thermal expansion set in a range of 0×10⁻⁶ K⁻¹ to 30×10⁻⁶ K⁻¹, and a total luminous transmittance set to 80% or greater. These parameters are described in detail below.

The thickness of the reinforcing layer 24 is preferably set in the range of 10 μm to 200 μm, and more preferably in the range of 10 μm to 100 μm. The reinforcing layer 24 with the thickness set in the above range can sufficiently prevent the stress caused by the expansion or contraction of the front surface protective substrate 20 from being transferred to the photoelectric converter.

The coefficient of thermal expansion of the reinforcing layer 24 is preferably set in the range of 0×10⁻⁶ K⁻¹ to 30×10⁻⁶ K⁻¹, and more preferably in the range of 5×10⁻⁶ K⁻¹ to 30×10⁻⁶ K⁻¹. The reinforcing layer 24 with the coefficient of thermal expansion set in the above range can prevent the stress caused by the expansion or contraction of the front surface protective substrate 20 from being transferred to the photoelectric converter if the front surface protective substrate 20 thermally expands or contracts, since the expansion or contraction of the reinforcing layer 24 is smaller than that of the front surface protective substrate 20.

The total luminous transmittance of the reinforcing layer 24 is preferably set to 80% or greater, and more preferably set in a range of 90% to 100%. The reinforcing layer 24 with the total luminous transmittance set in the above range can allow light to be transmitted to the photoelectric converter (the solar cells 10) efficiently. The method of measuring the total luminous transmittance is the same as described above.

The tensile modulus of elasticity of the reinforcing layer 24 is preferably set in a range of 1.0 GPa to 10.0 GPa, and more preferably in a range of 2 GPa to 5 GPa. The reinforcing layer 24 with the tensile modulus of elasticity set in the above range can sufficiently reduce the stress caused by the expansion or contraction of the front surface protective substrate 20.

At least one of the front and rear surfaces of the reinforcing layer 24 is preferably provided with a film having a water vapor transmission rate of 1.0 g/m²·day or smaller. The reinforcing layer 24 provided with such a film can prevent water vapor from entering the seal layer 26, so as to avoid hydrolysis of the sealing material in the seal layer 26. The water vapor transmission rate can be measured by an infrared sensing method prescribed in Appendix B to JIS K7129:2008 (Plastics—Film and sheeting—Determination of water vapour transmission rate—Instrumental method), for example.

At least one of the front and rear surfaces of the reinforcing layer 24 is preferably provided with a film having an oxygen transmission rate of 8.0 ml/m²·day or smaller. The reinforcing layer 24 provided with such a film can prevent oxidation from entering the seal layer 26, so as to avoid decomposition of the sealing material in the seal layer 26 caused by oxidation. The oxygen transmission rate can be measured in accordance with JIS K7126-1 (GC method).

The film provided in the reinforcing layer 24 may be formed by coating or vapor deposition, and preferably includes an inorganic composite material containing Si and O. Such a material may be a siloxane compound, and is particularly preferably polyorgano siloxane.

[Seal Layer]

The seal layer 26 is provided to protect the photoelectric converter. Examples of materials included in the seal layer 26 include thermoplastic resin such as an ethylene-vinyl acetate (EVA) copolymer, polyvinyl butyral (PVB), polyethylene terephthalate (PET), polyolefin (PO), and polyimide (PI), and thermosetting resin such as epoxy, urethane, and polyimide. A particularly preferable material is EVA or PO.

The seal layer 26 preferably has a thickness set in a range of 0.1 mm to 10 mm, and a tensile modulus of elasticity set in a range of 0.005 GPa to 0.05 GPa. These parameters are described in detail below.

The thickness of the seal layer 26 is preferably set in the range of 0.1 mm to 10 mm, and more preferably in the range of 0.2 mm to 1.0 mm. The seal layer 26 with the thickness set in the above range can sufficiently seal and protect the photoelectric converter.

The tensile modulus of elasticity of the seal layer 26 is preferably set in the range of 0.005 GPa to 0.05 GPa, and more preferably in the range of 0.01 GPa to 0.05 GPa. The seal layer 26 with the tensile modulus of elasticity set in the above range can sufficiently reduce the stress caused by the expansion or contraction of the front surface protective substrate 20.

[Rear Surface Protective Substrate]

The rear surface protective substrate 28 serves as a back sheet to protect the rear surface of the solar cell module 100. A material included in the rear surface protective substrate 28 may be at least one material selected from the group consisting of glass, fiber-reinforced plastic (FRP), polyimide (PI), cyclic polyolefin, polycarbonate (PC), polymethyl methacrylate (PMMA), polyether ether ketone (PEEK), polystyrene (PS), polyethylene terephthalate (PET), and polyethylene naphthalate (PEN). Examples of FRP include glass fiber-reinforced plastic (GFRP), carbon fiber-reinforced plastic (CFRP), and aramid fiber-reinforced plastic (AFRP). An example of GFRP may be glass epoxy. The material included in the rear surface protective substrate 28 preferably includes at least one material selected from the group consisting of FRP, PMMA, and PEEK. The rear surface protective substrate 28 is preferably made of fiber-reinforced resin such as FRP so as to have sufficient strength. The FRP may be unidirectional (UD) material in which fibers are oriented in one direction, or may be woven material woven out of fibers intersecting with each other. When using the UD material having resistance to expansion or contraction in the oriented direction of fibers, the rear surface protective substrate 28 can prevent damage to the solar cells 10 or a cutoff of the tab leads 12 depending on the direction of arrangement of the UD material. The rear surface protective substrate 28 is preferably made of CFRP which is resistant to warping and has a lighter weight. The rear surface protective substrate 28 may include titanium oxide, for example, for improving reflectivity so as to enhance the efficiency of power generation on the rear surface. The surface of the rear surface protective substrate 28 may be subjected to plating.

The thickness of the rear surface protective substrate 28 is preferably, but not necessarily, set in a range of 0.01 mm or greater to 10 mm or less, more preferably in a range of 0.05 mm or greater to 5.0 mm or less, and still more preferably in a range of 0.07 mm or greater to 1.0 mm or less. For the fiber-reinforced plastic, the diameter of each fiber is preferably the lower limit of the thickness. Setting the thickness in the above range can prevent or reduce warping of the rear surface protective substrate 28 and further reduce the weight of the solar cell module 100.

The rear surface protective substrate 28 having a reduced thickness (0.2 mm or less, for example) reduces the influence by the thermal contraction when a variation in temperature is caused in the rear surface protective substrate 28, or reduces its rigidity, in addition to a reduction in weight and entire thickness. The warp of the entire solar cell module 100 can be prevented or reduced accordingly.

The rear surface protective substrate 28 having a reduced thickness can enhance gas removing performance inside the solar cell module. While the seal layer 26 including EVA may generate acetic acid by decomposition of EVA, for example, the rear surface protective substrate 28 having a reduced thickness allows the acetic acid to be easily emitted outward.

When the rear surface protective substrate 28 with the thickness reduced includes the fiber-reinforced plastic of the UD material, the UD material can be partly layered as necessary to reinforce a desired part, so as to vary the characteristics depending on the site of the rear surface protective substrate 28. The UD material may be layered such that the fibers in the UD material are oriented in the same direction, or the fibers are oriented in different directions, such as directions perpendicular to each other, depending on the desired characteristics.

The reduced thickness allows the rear surface protective substrate 28 to be bonded to conform to the shape of the seal layer 26 (the surface to be bonded), avoiding the entrance of bubbles between the seal layer 26 and the rear surface protective substrate 28. The reduced thickness also allows the rear surface protective substrate 28 to be bonded to the seal layer 26 so as to be fitted for the shape of the front surface protective substrate 20 having a curved surface, for example. This facilitates the manufacture of the solar cell module 100 having a curved shape, while avoiding the entrance of bubbles. A film module prepared such that the rear surface protective substrate 28, the seal layer 26, and the reinforcing layer 24 are preliminarily bonded together facilitates the bonding to the front surface protective substrate 20 due to the flexibility of the film module itself. The rear surface protective substrate 28 having high flexibility avoids a local load applied to the solar cells 10, so as to prevent damage to the solar cells 10 when the respective layers are stacked to manufacture the solar cell module 100 having a curved shape, for example. The prevention of damage to the solar cells 10 is particularly advantageous to the solar cell module 100 which further includes the gel polymer layer 22 described above. The rear surface protective substrate 28 having a reduced thickness allows the seal layer 26 to be rapidly heated to be cross-linked, so as to not only reduce the time to manufacture the solar cell module 100 but also prevent thermal deformation of the front surface protective substrate 20.

The rear surface protective substrate 28 preferably has a thickness set in a range of 0.01 mm to 10 mm, a tensile modulus of elasticity set in a range of 1.0 GPa to 100.0 GPa, and a coefficient of thermal expansion set in a range of 0×10⁻⁶ K⁻¹ to 30×10⁻⁶ K⁻¹. These parameters are described in detail below.

The thickness of the rear surface protective substrate 28 is preferably set in the range of 0.01 mm to 10 mm, and more preferably in the range of 0.05 mm to 5.0 mm. The rear surface protective substrate 28 with the thickness set in the above range can sufficiently protect the rear surface of the solar cell module 100.

The tensile modulus of elasticity of the rear surface protective substrate 28 is preferably set in the range of 1.0 GPa to 100.0 GPa, and more preferably in the range of 2.3 GPa to 2.5 GPa. The rear surface protective substrate 28 with the tensile modulus of elasticity set in the above range can sufficiently protect the rear surface of the solar cell module 100.

The coefficient of thermal expansion of the rear surface protective substrate 28 is preferably set in the range of 0×10⁻⁶ K⁻¹ to 30×10⁻⁶ K⁻¹, and more preferably in the range of 2×10⁻⁶ K⁻¹ to 25×10⁻⁶ K⁻¹. The rear surface protective substrate 28 with the coefficient of thermal expansion set in the above range can improve the resistance to thermal shock.

The tensile moduli of elasticity of the respective layers described above preferably fulfil the relation of A<B<C, where A is the tensile modulus of elasticity of the material included in the gel polymer layer, B is the tensile modulus of elasticity of the material included in the seal layer, and C is the tensile modulus of elasticity of the material included in the reinforcing layer. The coefficient of thermal expansion is preferably greater for the material included in the front surface protective substrate than for each of the material included in the rear surface protective substrate and the material included in the reinforcing layer. When the tensile moduli of elasticity (A, B, and C) of the gel polymer layer, the seal layer, and the reinforcing layer fulfills the relation of A<B<C, the gel polymer can reduce the deformation of the front surface protective substrate caused by a change in temperature. When the coefficient of thermal expansion is greater for the material included in the front surface protective substrate than for each of the material included in the rear surface protective substrate and the material included in the reinforcing layer, the reinforcing layer can reduce the deformation of the front surface protective substrate caused by a change in temperature.

Next, modified examples (FIG. 3 and FIG. 4) of the solar cell module according to the present embodiment are illustrated below.

FIG. 3 shows a structure in which the gel polymer layer 22 and the reinforcing layer 24 are arranged in the order opposite to that shown in FIG. 2. In particular, the front surface protective substrate 20, the reinforcing layer 24, the gel polymer layer 22, the photoelectric converter (the seal layer 26, the solar cells 10, and the tab leads 12), and the rear surface protective substrate 28 are sequentially arranged. The reinforcing layer 24 barely follows the deformation of the adjacent front surface protective substrate 20 caused by a change in circumferential temperature, and the gel polymer layer 22 adjacent to the reinforcing layer 24 can further reduce the deformation if the reinforcing layer 24 is deformed. The deformation of the front surface protective substrate 20 thus has little influence on the photoelectric converter, preventing damage to the solar cells 10 or a cutoff of the tab leads 12 accordingly.

FIG. 4 differs from FIG. 2 in the structure including two seal layers (seal layers 26A and 26B). The seal layer 26A of the two seal layers is arranged to seal and protect the photoelectric converter, and the other seal layer 26B is arranged between the gel polymer layer 22 and the reinforcing layer 24. The layer 26B, which does not seal any members but includes the same material as the seal layer 26A, is referred to herein as a “seal layer”. The gel polymer layer 22 follows the deformation of the adjacent front surface protective substrate 20 derived from a change in circumferential temperature. The presence of the seal layer 26B contributes to reducing the deformation transferred from the front surface protective substrate 20 and not reduced sufficiently only by the gel polymer layer 22. The deformation of the front surface protective substrate 20 thus has little influence on the photoelectric converter, preventing damage to the solar cells 10 or a cutoff of the tab leads 12 accordingly.

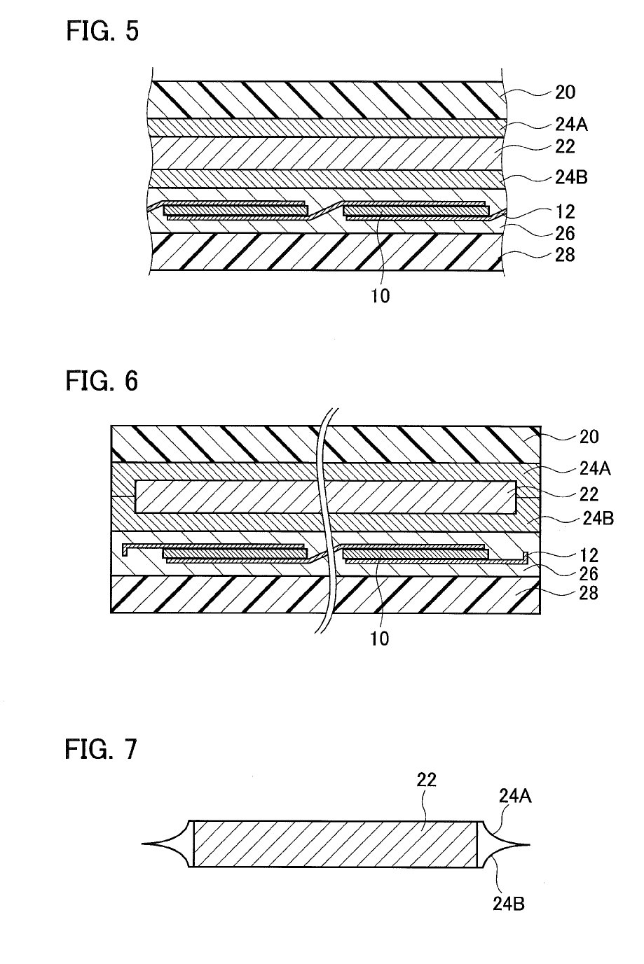

The solar cell module according to the present embodiment preferably includes two reinforcing layers which interpose the gel polymer layer. FIG. 5 shows such a structure including two reinforcing layers (reinforcing layers 24A and 24B), in which the gel polymer layer 22 is interposed between the two reinforcing layers 24A and 24B. The use of the gel polymer layer 22 in the solar cell module 100 would cause a change in color or embrittlement if impurities contained in the gel polymer are dispersed into the seal layer 26 or the front surface protective substrate 20. Examples of such impurities include an additive (such as an UV absorber and a plasticizer) contained in the gel polymer, a low molecular weight component (such as water and a gelling agent including silicone oil) mixed so as to stabilize the shape, and an unreacted monomer. The arrangement of the gel polymer layer 22 isolated by the two reinforcing layers 24A and 24B shown in FIG. 5 can avoid the dispersion of the additive or other components described above. The present embodiment thus can achieve the effect of preventing the dispersion of the additive or other components contained in the gel polymer, in addition to the effect of preventing damage to the solar cells or a cutoff of the tab leads as described by reference to FIG. 2 to FIG. 4.

The reinforcing layers 24A and 24B having this configuration are also preferably provided with the film with the water vapor transmission rate of 1.0 g/m²·day or smaller and/or the oxygen transmission rate of 8.0 ml/m²·day or smaller, as described above. Providing such a film can sufficiently achieve the effect of preventing the dispersion of the additive or other components contained in the gel polymer.

The gel polymer layer 22 shown in FIG. 5 is more preferably entirely sealed between the two reinforcing layers (24A and 24B). FIG. 6 illustrates such a configuration. FIG. 6 is a cross-sectional view showing the entire solar cell module 100 taken along the extending line in the y-axis direction overlapping with the line A-A in FIG. 1, while omitting the middle part of the solar cell module 100. FIG. 6 illustrates the gel polymer layer 22 which is entirely sealed between the two reinforcing layers 24A and 24B. FIG. 5 shows the structure in which the gel polymer layer 22 is open to the outside on both sides, which could lead the additive or other components to be dispersed through the open sides on a long-term basis. The gel polymer layer 22 shown in FIG. 6 is thus entirely sealed between the two reinforcing layers 24A and 24B. Namely, the entire gel polymer layer 22 including the side surfaces is sealed between the reinforcing layers 24A and 24B. This configuration can achieve the effect of preventing the dispersion of the additive or other components contained in the gel polymer more reliably than the configuration shown in FIG. 5. While FIG. 6 schematically illustrates the state of the gel polymer layer 22 sealed between the reinforcing layers 24A and 24B, FIG. 7 illustrates the actual state of the gel polymer layer 22 laminated between the reinforcing layers 24A and 24B in a film state.

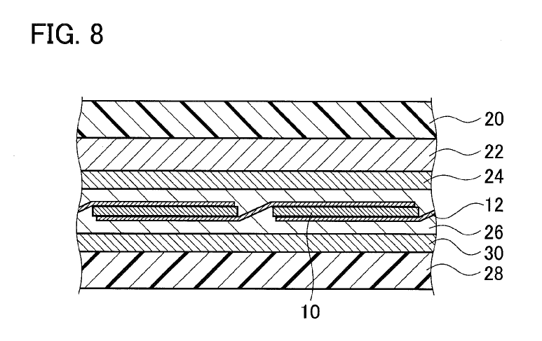

The solar cell module according to the present embodiment preferably further includes a reinforcing layer having insulating properties on the rear surface protective substrate toward the photoelectric converter. The rear surface protective substrate 28, particularly when including a conductive base such as CFRP, may lead to a problem of a leakage current. FIG. 8 illustrates the arrangement of the reinforcing layer 30 having insulating properties between the rear surface protective substrate 28 and the photoelectric converter so as to block a leakage current. The reinforcing layer 30 preferably includes the material used for the reinforcing layers described above and having higher insulating properties.

The reinforcing layer according to this configuration preferably additionally includes a white pigment such as titanium oxide to improve reflectance so as to enhance the efficiency of power generation. Alternatively, the surface of the reinforcing layer may be subjected to plating to improve the reflectance.

<Residential Structure Material>

A residential structure material according to the present embodiment includes the solar cell module according to the present embodiment described above. Examples of residential structure materials include a roof and a wall. A current generated by the solar cell module according to the present embodiment of any type of residential structure material is supplied to be used for driving an electrical device.

<Outdoor Facility>

An outdoor facility according to the present embodiment includes the solar cell module according to the present embodiment described above. Examples of outdoor facilities include a tent, a carport, and a plant roof using a folded-plate roof having a low load-bearing capacity. A current generated by the solar cell module according to the present embodiment of any type of outdoor facility is supplied to be used for driving an electrical device.

<Transport>

A transport according to the present embodiment includes the solar cell module according to the present embodiment described above. Examples of transports include a vehicle such as an automobile, a train, and a ship. For an automobile, the solar cell module according to the present embodiment is preferably mounted on a top surface of a body of the automobile such as a hood and a roof. A current generated by the solar cell module according to the present embodiment of any type of transport is supplied to an electrical device, such as a fan and a motor, so as to be used for driving or controlling the electrical device.

### EXAMPLES

Hereinafter, the present embodiment is described in more detail with reference to examples, but is not limited to these examples.

### Example 1

A solar cell module of this example having the layered structure shown in FIG. 2 was analyzed with Femtet (registered trademark; available from Murata Software Co., Ltd.). The specifications of the respective layers are as follows:

Rear surface protective substrate: carbon fiber-reinforced plastic (CFRP) with thickness of 1 mm

Seal layer: ethylene-vinyl acetate (EVA) copolymer (tensile modulus of elasticity at 25° C.: 0.03 GPa)

Reinforcing layer: polyethylene terephthalate (PET) with thickness of 0.1 mm (coefficient of thermal expansion: 20×10⁻⁶ K⁻¹)

Gel polymer layer: silicone gel with thickness of 1.0 mm (tensile modulus of elasticity at 25° C.: 2.2 kPa, total luminous transmittance: 90%)

Front surface protective substrate: polycarbonate with thickness of 1 mm (tensile modulus of elasticity at 25° C.: 7 GPa, total luminous transmittance: 90%)

<Evaluation>

The solar cell module described above was subjected to a temperature cycle test to undergo a simulation when the temperature was changed from 145° C. to 25° C. in accordance with JIS C8917, so as to analyze the shifted amount of the solar cells before and after the test and the number of cycles until tab leads were cut off. Table 1 lists the analysis results. The number of cycles until the tab leads were cut off was evaluated according to the following criteria:

Evaluation Criteria

A: No cutoff before 200 cycles

B: Cutoff between 50 to 200 cycles

C: Cutoff before 50 cycles

### Examples 2 to 5

The solar cell modules of these examples were evaluated in the same manner as Example 1, except that the respective gel polymer layers were changed to the corresponding layers shown in Table 1. Table 1 lists the evaluation results.

### Reference Examples 1 to 5

The solar cell modules of these examples were evaluated in the same manner as Examples 1 to 5, except that no reinforcing layer was stacked. Table 1 lists the evaluation results.

TABLE 1

| | Gel Polymer Layer | | | | |
|---|---|---|---|---|---|
| | | Thickness | Tensile Modulus of | Solar Cell Shifted | Repeated Number of Temperature |
| | Material | [mm] | Elasticity [Pa] | Amount [μm] | Cycle Test until Cutoff of Tab Lead |
| Example 1 | Silicone Gel | 1.0 | 2200 | 22.4 | A |
| Example 2 | Silicone Gel | 1.0 | 22000 | 22.6 | A |
| Example 3 | Silicone Gel | 1.0 | 100000 | 23.3 | A |
| Example 4 | Silicone Gel | 1.0 | 220000 | 24.4 | B |
| Example 5 | Silicone Gel | 1.0 | 2200000 | 33.9 | C |
| Reference | Silicone Gel | 1.0 | 2200 | 24.2 | B |
| Example 1 | | | | | |
| Reference | Silicone Gel | 1.0 | 22000 | 24.4 | B |
| Example 2 | | | | | |
| Reference | Silicone Gel | 1.0 | 100000 | 25.2 | B |
| Example 3 | | | | | |
| Reference | Silicone Gel | 1.0 | 220000 | 26.4 | C |
| Example 4 | | | | | |
| Reference | Silicone Gel | 1.0 | 2200000 | 37.0 | C |
| Example 5 | | | | | |

### Example 2A

A solar cell module of this example having the same configuration as Example 2 was actually fabricated and evaluated in the same manner as Example 2, except that the temperature was changed from 90° C. to −40° C. in the temperature cycle test. Table 2 lists the evaluation results.

### Reference Example 2A

A solar cell module of this example having the same configuration as Reference Example 2 was actually fabricated and evaluated in the same manner as Example 2, except that the temperature was changed from 90° C. to −40° C. in the temperature cycle test. Table 2 lists the evaluation results.

### Comparative Example 1

A solar cell module of this example was fabricated and evaluated in the same manner as Example 2A, except that neither the reinforcing layer nor the gel polymer layer was stacked. Table 2 lists the evaluation results.

TABLE 2

| | Gel Polymer Layer | | | |
|---|---|---|---|---|
| | | Thickness | Tensile Modulus | Repeated Number of Temperature |
| | Material | [mm] | of Elasticity [Pa] | Cycle Test until Cutoff of Tab Lead |
| Example 2A | Silicone Gel | 1.0 | 22000 | A |
| Reference | Silicone Gel | 1.0 | 22000 | B |
| Example 2A | | | | |
| Comparative | None | — | — | C |
| Example 1 | | | | |

The results shown in Table 1 and Table 2 revealed that the shifted amount of the solar cells in each of Examples 1 to 4 greatly differs from that of Example 5. In particular, the shifted amount of the solar cells is significantly small when the tensile modulus of elasticity of the gel polymer layer is less than 0.5 MPa. The load exerted on the tab leads is presumed to be smaller as the shifted amount of the solar cells is smaller, avoiding a cutoff of the tab leads. Setting the tensile modulus of elasticity of the gel polymer layer to less than 0.5 MPa thus can greatly avoid a cutoff of the tab leads.

The solar cell module of Example 1 including the reinforcing layer resulted in the smaller shifted amount of the solar cells than the solar cell module of Reference Example 1 with no reinforcing layer included. In addition, the repeated number of cycles of the temperature change until the tab leads were cut off is greater for Example 1 than for Reference Example 1. The same is also applied to Examples 2 to 5 with respect to the corresponding Reference Examples 2 to 5. These results revealed that the presence of the reinforcing layer contributes to preventing a cutoff of the tab leads.

The entire contents of Japanese Patent Application No. P2017-026998 (filed on Feb. 16, 2017) and Japanese Patent Application No. P2017-210977 (filed on Oct. 31, 2017) are herein incorporated by reference.

### INDUSTRIAL APPLICABILITY

The present invention can provide a solar cell module resistant to damage to solar cells or cutoff of tab leads when a change in temperature is caused.

### REFERENCE SIGNS LIST

10 SOLAR CELL (PHOTOELECTRIC CONVERTER)
12 TAB LEAD
14 CONNECTING LEAD
16 SOLAR CELL STRING (PHOTOELECTRIC CONVERTER)
20 FRONT SURFACE PROTECTIVE SUBSTRATE
22 GEL POLYMER LAYER
24 REINFORCING LAYER
26 SEAL LAYER
28 REAR SURFACE PROTECTIVE SUBSTRATE
30 REINFORCING LAYER
100 SOLAR CELL MODULE

1. A solar cell module comprising:
a front surface protective substrate including transparent resin;
a rear surface protective substrate;
a photoelectric converter including at least one solar cell connected via a tab lead and arranged between the front surface protective substrate and the rear surface protective substrate; and
at least one reinforcing layer, at least one seal layer, and a gel polymer layer which are arranged between the photoelectric converter and the front surface protective substrate.

2. The solar cell module according to claim 1, wherein the at least one reinforcing layer comprises two reinforcing layers, and the gel polymer layer is interposed between the two reinforcing layers.

3. The solar cell module according to claim 2, wherein the gel polymer layer is entirely sealed between the two reinforcing layers.

4. The solar cell module according to claim 1, wherein a tensile modulus of elasticity A of a material included in the gel polymer layer, a tensile modulus of elasticity B of a material included in the at least one seal layer, and a tensile modulus of elasticity C of a material included in the at least one reinforcing layer fulfil a relation of A<B<C, and a coefficient of thermal expansion is greater for the material included in the front surface protective substrate than for each of a material included in the rear surface protective substrate and the material included in the at least one reinforcing layer.

5. The solar cell module according to claim 1, wherein the front surface protective substrate has a thickness set in a range of 0.1 mm to 15 mm, a tensile modulus of elasticity set in a range of 1.0 GPa to 10.0 GPa, and a total luminous transmittance set to 80% or greater.

6. The solar cell module according to claim 1, wherein the at least one reinforcing layer has a thickness set in a range of 10 μm to 200 μm, a coefficient of thermal expansion set in a range of 0×10⁻⁶ K⁻¹ to 30×10⁻⁶ K⁻¹, and a total luminous transmittance set to 80% or greater.

7. The solar cell module according to claim 1, wherein the gel polymer layer has a thickness set in a range of 5% to 99% of a thickness of the front surface protective substrate, a tensile modulus of elasticity set in a range of 0.1 kPa or greater to less than 0.5 MPa, and a total luminous transmittance set to 80% or greater.

8. The solar cell module according to claim 1, wherein the at least one seal layer has a thickness set in a range of 0.1 mm to 10 mm, and a tensile modulus of elasticity set in a range of 0.005 GPa to 0.05 GPa.

9. The solar cell module according to claim 1, wherein the rear surface protective substrate has a thickness set in a range of 0.01 mm to 10 mm, a tensile modulus of elasticity set in a range of 1.0 GPa to 100.0 GPa, and a coefficient of thermal expansion set in a range of 0×10⁻⁶ K⁻¹ to 30×10⁻⁶ K⁻¹.

10. The solar cell module according to claim 1, wherein the rear surface protective substrate includes fiber-reinforced resin.

11. The solar cell module according to claim 1, wherein at least one of front and rear sides of the at least one reinforcing layer is provided with a film having a water vapor transmission rate of 1 g/m²·day or smaller.

12. The solar cell module according to claim 1, wherein at least one of front and rear sides of the at least one reinforcing layer is provided with a film having an oxygen transmission rate of 8.0 ml/m²·day or smaller.

13. The solar cell module according to claim 11, wherein the film includes a material containing Si and O.

14. The solar cell module according to claim 1, wherein a gel polymer included in the gel polymer layer includes at least one gel selected from the group consisting of silicone gel, urethane gel, acrylic gel, and styrene gel.

15. The solar cell module according to claim 1, further comprising a reinforcing layer having an insulating property on the rear surface protective substrate toward the photoelectric converter.

16. A residential structure material comprising the solar cell module according to claim 1.

17. An outdoor facility comprising the solar cell module according to claim 1.

18. A transport comprising the solar cell module according to claim 1.
